(19) United States
(12) Patent Application Publication
(10) Pub. No.: US 2026/0372089 A1
(43) Pub. Date: Nov. 19, 2026

(54) PACKAGE STRUCTURE AND METHOD FOR FORMING THE SAME

(71) Applicant: Taiwan Semiconductor Manufacturing Company, Ltd., Hsinchu (TW)

(72) Inventors: Chien-Hao HSU, Zhubei City (TW); Kuan-Min WANG, Hsinchu City (TW); Kuo-Chin CHANG, Chiayi City (TW); Kathy Wei YAN, Hsinchu (TW); Jun HE, Zhubei City (TW)

(73) Assignee: Taiwan Semiconductor Manufacturing Company, Ltd., Hsinchu (TW)

(21) Appl. No.: 19/751,262

(22) Filed: Jul. 23, 2026

Related U.S. Application Data
(63) Continuation of application No. 18/600,981, filed on Mar. 11, 2024.
(60) Provisional application No. 63/617,123, filed on Jan. 3, 2024.

(51) Int. Cl. H10W 40/25; H10W 20/42; H10W 70/65; H10W 72/00; H10W 72/29; H10W 72/90; H10W 90/00

(52) U.S. Cl. CPC H10W 40/255; H10W 20/42; H10W 70/65; H10W 72/01908; H10W 72/29; H10W 72/923; H10W 72/942; H10W 90/724

(57) ABSTRACT

A package structure is provided. The package structure includes forming a redistribution structure, a bonding element above the redistribution structure, and a semiconductor die above the bonding element. The semiconductor die includes an interconnect structure. The interconnect structure includes a first group of metal lines electrically connected to the bonding element. The metal lines in the first group vertically overlap with each other. The semiconductor die further includes a first conductive pad between the bonding element and the first group of metal lines. A bottommost one of the metal lines in the first group is a first metal line. In a plan view, a dimension of the first metal line along a first horizontal direction is less than a dimension of the first conductive pad along the first horizontal direction. The package structure includes an underfill material encapsulating the bonding element.

### PRIORITY CLAIM

This application is a continuation application of U.S. application Ser. No. 18/600,981, filed Mar. 11, 2024 and entitled "METHOD FOR FORMING DEVICE SUBSTRATE, METHOD FOR FORMING PACKAGE STRUCTURE AND PACKAGE STRUCTURE", which claims the benefit of U.S. Provisional Application No. 63/617,123, filed on Jan. 3, 2024 and entitled “Package structure with thermal Via configuration,” which are incorporated herein by reference.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature size (i.e., the smallest component that can be created using a fabrication process) has decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which utilize a smaller area or are lower in height, have been developed to package the semiconductor devices.

New packaging technologies have been developed to further improve the density and functionalities of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1B and 1C are cross-sectional views illustrating the formation of a device substrate at various intermediate stages, in accordance with some embodiments of the disclosure.

FIG. 1B-1 is a plan view illustrating the configuration of an opening of a polymer layer, a redistribution layer, a topmost via of a thermal conduction structure, and a topmost via of an electrical routing structure shown in FIG. 1B, in accordance with some embodiments of the disclosure.

FIG. 1B-2 is a plan view illustrating the configuration of vias of a thermal conduction structure and vias of an electrical routing structure shown in FIG. 1B in different levels, in accordance with some embodiments of the disclosure.

FIG. 1C-1 is a plan view of a semiconductor die shown in FIG. 1C, in accordance with some embodiments of the disclosure.

FIGS. 2A, 2B, 2C and 2D are cross-sectional views illustrating the formation of a package structure at various intermediate stages, in accordance with some embodiments of the disclosure.

FIG. 2D-1 is an enlarged view of the package structure of FIG. 2D to illustrate a thermal conduction path through a thermal conduction structure, in accordance with some embodiments.

FIG. 3-1 is a modification of FIG. 2D-1, in accordance with some embodiments of the disclosure.

FIG. 3-2 is a plan view illustrating the configuration of vias of a thermal conduction structure shown in FIG. 3-1, in accordance with some embodiments of the disclosure.

FIG. 4-1 is a modification of FIG. 2D-1, in accordance with some embodiments of the disclosure.

FIG. 4-2 is a plan view illustrating the configuration of vias of a thermal conduction structure shown in FIG. 4-1, in accordance with some embodiments of the disclosure.

FIG. 5 is a modification of FIG. 2D-1, in accordance with some embodiments of the disclosure.

FIG. 6-1 is a modification of FIG. 2D-1, in accordance with some embodiments of the disclosure.

FIG. 6-2 is a plan view illustrating the configuration of vias of a thermal conduction structure shown in FIG. 6-1, in accordance with some embodiments of the disclosure.

FIG. 7 is a modification of FIG. 2D-1, in accordance with some embodiments of the disclosure.

FIG. 8A is a modification of FIG. 1C-1, in accordance with some embodiments of the disclosure.

FIG. 8B is a modification of FIG. 1C-1, in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as "substantially parallel" or "substantially perpendicular" are to be interpreted as not to exclude insignificant deviation from the specified arrangement and may include for example deviations of up to 10°. The word "substantially" does not exclude "completely" e.g. a composition which is "substantially free" from Y may be completely free from Y.

Terms such as "about" in conjunction with a specific distance or size are to be interpreted so as not to exclude insignificant deviation from the specified distance or size and may include for example deviations of up to 10%. The term "about" in relation to a numerical value x may mean x ±5 or 10%.

Some embodiments of the disclosure are described. Additional operations can be provided before, during, and/or after the stages described in these embodiments. Some of the stages that are described can be replaced or eliminated for different embodiments. Additional features can be added to the structures of the embodiments. Some of the features described below can be replaced or eliminated for different embodiments. Although some embodiments are discussed with operations performed in a particular order, these operations may be performed in another logical order.

Embodiments of the disclosure may relate to 3D packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Many heat dissipation solutions have been developed for high-performance computing packaging products. The mainstream of these heat dissipation solutions focuses on conducting heat from the device heat source to the heat sink through thermal interface material (TIM). However, it is gradually limited by the size of the silicon die (chip) and the thermal resistance of the interface between TIMs increases.

Embodiments of a device substrate are provided. The device substrate includes an interconnect structure and a redistribution layer over the interconnect structure. The interconnect structure may provide a thermal conduction structure which includes a vertically stacked group of metal lines and vias directly under a bonding pad of the redistribution layer.

In addition, the embodiments of the present disclosure provide the package structure, which includes a redistribution structure and a semiconductor die over the redistribution structure. The semiconductor die is singulated from the device substrate. Because the semiconductor die includes a thermal conduction structure, the heat generated from the integrated circuits may be efficiently dissipated to the redistribution structure and then to a heat spreader. Therefore, the heat dissipation issue of the package structure may be alleviated.

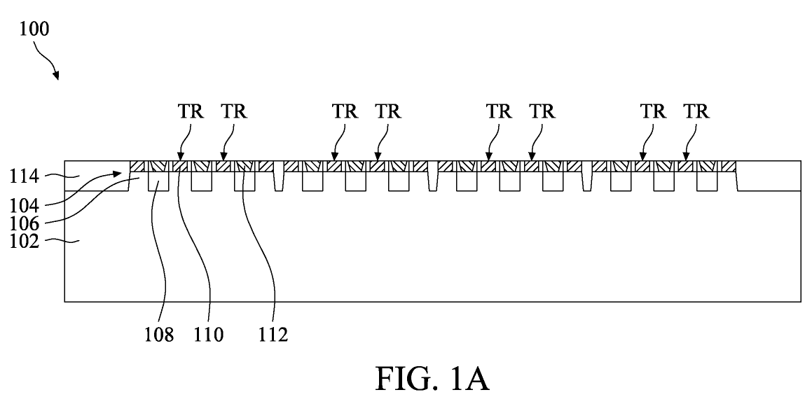

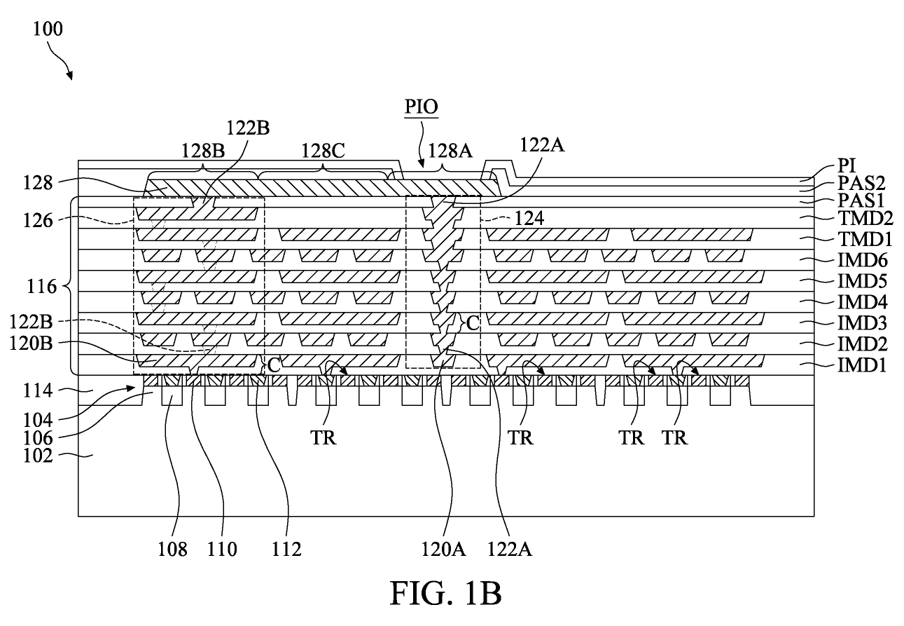

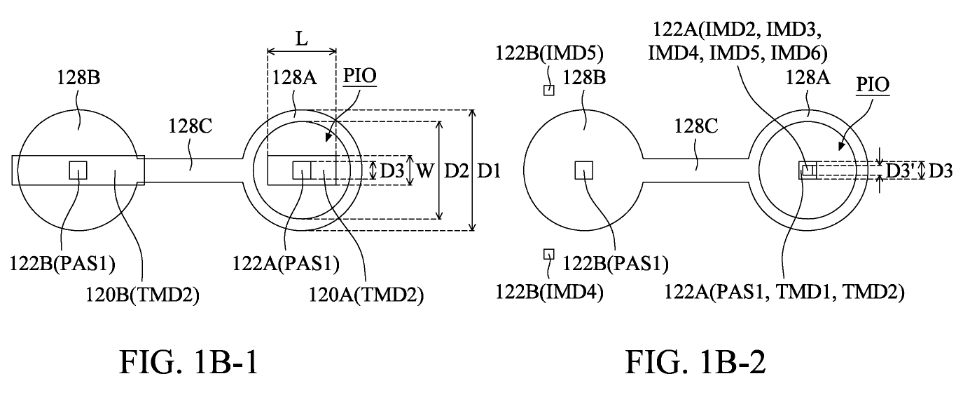

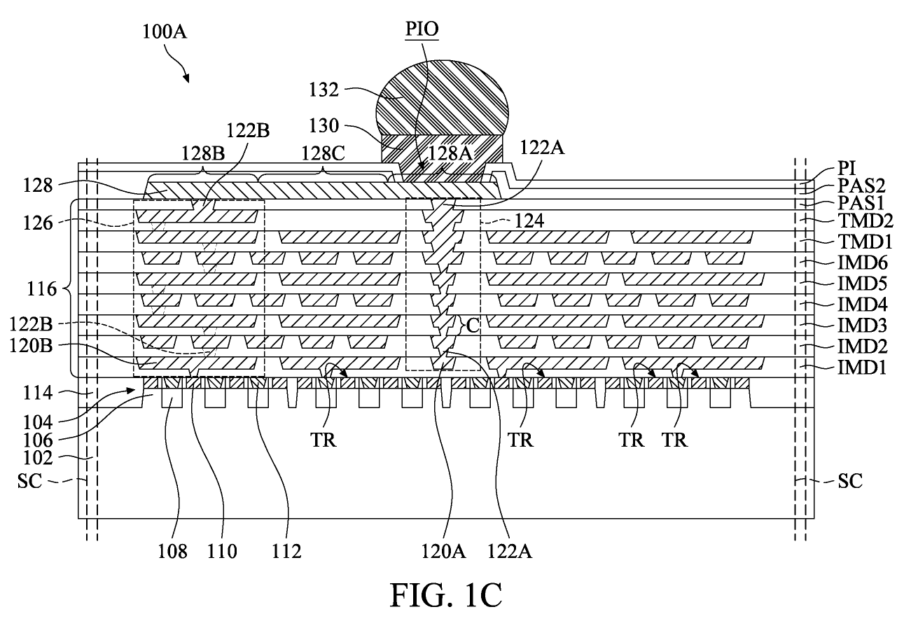

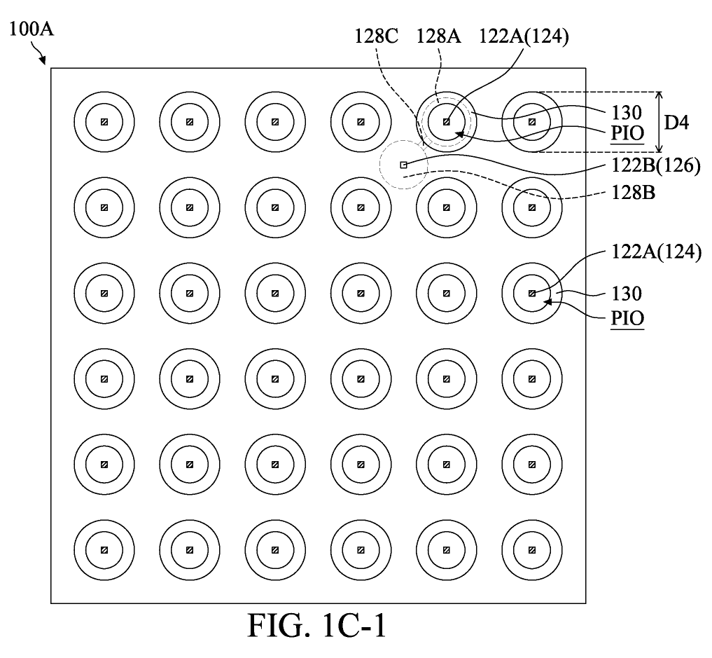

FIGS. 1A, 1B and 1C are cross-sectional views illustrating the formation of a device substrate at various intermediate stages, in accordance with some embodiments of the disclosure.

FIG. 1A illustrates a device substrate 100, in accordance with some embodiments. The device substrate 100 includes a semiconductor substrate 102, a device layer 104 formed on the semiconductor substrate 102, as shown in FIG. 1A, in accordance with some embodiments.

The device substrate 100 will be singulated into multiple semiconductor dies which are designed for mobile applications, and may be logic dies (e.g., including central processing unit (CPU), graphics processing units (GPU), system-on-a-chips (SoC), application processors (AP), microcontroller, etc.), memory dies (e.g., dynamic random access memory (DRAM) dies, static random access memory (SRAM) dies, etc.), power management die (e.g., power management integrated circuit (PMIC) die), a radio frequency (RF) dies, sensor dies, micro-electro-mechanical-system (MEMS) dies, signal processing dies (e.g., digital signal processing (DSP) dies), front-end dies (e.g., analog front-end (AFE) dies), high-performance computing (HPC) dies, artificial intelligence (AI) dies, automotive dies, the like, or combinations thereof.

In some embodiments, the substrate 102 is a semiconductor wafer e.g., a silicon wafer (substrate). In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The device layer 104 includes transistors TR which are electrically coupled to one other to form integrated circuits, as shown in FIG. 1A, in accordance with some embodiments. However, this is not a limitation of the present disclosure. The device layer 104 may include various passive and active microelectronic devices (not shown), such as resistors, capacitors, inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, FinFETs, nanostructure transistors (e.g., gate-all around transistors), other types of transistors, and/or any combinations thereof.

In some embodiments where the transistors TR are FinFETs, the transistors TR include fin structures 106 functioning as channels of the transistors TR, metal gates 110 functioning as gate terminals of the transistors TR, and epitaxial source/drain features 108 and metal contact plugs 112 together functioning as source or drain terminals of the transistors TR, as shown in FIG. 1A, in accordance with some embodiments.

A dielectric layer 114 is formed on the semiconductor substrate 102 to surround microelectronic components of the device layer 104, as shown in FIG. 1A, in accordance with some embodiments. The dielectric layer 114 may include shallow trench isolation (STI) feature, spacer layers, an interlayer dielectric layer (ILD), and/or other suitable dielectric features. The dielectric layer 114 is made of more than one dielectric materials such as silicon oxide, silicon nitride and/or silicon oxynitride.

FIG. 1B illustrates a device substrate 100 after the formation of an interconnect structure 116, a redistribution layer 128, passivation layers PAS1 and PAS2 and a polymer layer PI, in accordance with some embodiments. An interconnect structure 116 is formed over the device layer 104 and the dielectric layer 114, as shown in FIG. 1B, in accordance with some embodiments.

The interconnect structure 116 is a multi-layered or multi-leveled structure, in accordance with some embodiments. The interconnect structure 116 includes stacked levels of dielectric layers, e.g., including, in sequence stacked over the device layer 104, intermetal dielectric layers IMD1-IMD6, top metal dielectric layers TMD1-TMD2, and a first passivation layer PAS1, as shown in FIG. 1B, in accordance with some embodiments.

The interconnect structure 116 further includes conductive connectors C disposed in the respective dielectric layers IMD1-IMD6, TMD1-TMD2 and PAS1, in accordance with some embodiments. The conductive connectors C are electrically conductive features, e.g., metal lines 120 (including 120A and 120B), vias 122 (including 122A and 122B), or a combination of metal lines 120 and vias 122, in accordance with some embodiments. The vias 122 connect metal lines 120 in different levels (or different planes), in accordance with some embodiments.

The interconnect structure 116 provides a thermal conduction structure 124 and an electrical routing structure 126, in accordance with some embodiments. A group of conductive connectors C including the metal lines 120A and the vias 122A is defined as a thermal conduction structure 124, as shown in FIG. 1B, in accordance with some embodiments. Although one thermal conduction structure 124 is shown in FIG. 1B, there may be more than one thermal conduction structure 124, depending on the number of bonding pads in the resulting device substrate. The thermal conduction structure 124 is configured to conduct the heat generated from the integrated circuits of the device layer 104 during operation to a package substrate, in accordance with some embodiment. This will be discussed in detail later.

One conductive connector C of the thermal conduction structure 124 in a level (i.e., one of the dielectric layers IMD1-IMD6, TMD1-TMD2 and PAS1) may be one metal line 120A (e.g., in the dielectric layer IMD1), a pair of one metal line 120A and one via 122A (e.g., in the dielectric layers IMD2-IMD6 and TMD1-TMD2), or one via 122A (e.g., in the dielectric layer PAS1), in accordance with some embodiments. In some other embodiments, the conductive connector C of the thermal conduction structure 124 in a level may include one metal line 120A and more than vias 122, e.g., two, three or more.

The thermal conduction structure 124 is isolated from the device layer 104 by the first intermetal dielectric layer IMD1, in accordance with some embodiments. In specific, the bottommost connector C of the thermal conduction structure 124 (i.e., the metal line 120A disposed in the intermetal dielectric layer IMD1) is isolated from the underlying integrated circuits (e.g., the transistors TR), in accordance with some embodiments. The bottom surface of the bottommost metal line 120A is not in contact with the metal gates 110 or the contact plugs 112, and is entirely in contact with and covered by the first intermetal dielectric layer IMD1, in accordance with some embodiments.

The conductive connectors C of the thermal conduction structure 124 are vertically stacked and substantially aligned with each other, in accordance with some embodiments. In some embodiments, the vias 122A of the thermal conduction structure 124 in different dielectric layers overlap with one other. As a result, the thermal conduction structures 124 may provide a substantially straight thermal conduction path without turns, in accordance with some embodiments. The conductive connectors C of the thermal conduction structure 124 may provide the shortest vertical thermal conduction path in the interconnect structure 116, in accordance with some embodiments.

A group of conductive connectors C including the metal lines 120B and the vias 122B is defined as an electrical routing structure 126, as shown in FIG. 1B, in accordance with some embodiments. Although one electrical routing structures 126 is shown in FIG. 1B, there may be more than one electrical routing structures 126, depending on the design requirements for the integrated circuits. The metal lines 120B are configured to provide horizontal electrical routing, and vias 122A are configured to provide a vertical connection between features and/or vertical electrical routing. Some of the vias 122B are shown as dash lines, which indicates that they are not in the cross-sectional view, and may be in front of or behind the cross-sectional view. The transistors TR are electrically coupled to one another to form the integrated circuits through the conductive connectors C of the electrical routing structures 126, in accordance with some embodiments. The electrical routing structures 126 further electrically connects the integrated circuits to an external device, in accordance with some embodiments.

In the same level, the conductive connector C of the thermal conduction structure 124 is physically isolated from the conductive connectors C of the electrical routing structure 126 by the dielectric layer IMD1-IMD6, TMD1-TMD2 or PAS1, which may avoid the negative impact on the signal transmission of the electrical routing structures 126 by the thermal conduction structures 124, in accordance with some embodiments.

The formation of the interconnect structure 116 includes forming the first-level dielectric layer (e.g., the intermetal dielectric layer IMD1) and the conductive connectors C therein, and then forming the second-level dielectric layer (e.g., the intermetal dielectric layer IMD2) and the conductive connectors C therein. The formation of a dielectric layer and conductive components is repeated until the top-level dielectric layer (e.g., the first passivation layer PAS1) and the conductive connectors C therein are formed.

In some embodiments, the dielectric layers IMD1-IMD6, TMD1-TMD2 and PAS1 may be made of one or more dielectric materials, such as silicon oxide (SiO), silicon nitride (SiN), silicon oxynitride (SiON), silicon carbide (SiC), aluminum oxide (Al₂O₃), a dielectric material with low dielectric constant (low-k) such as SiCOH, SiOCN, SiOC, or a combination thereof. In some embodiments, the dielectric materials may be extremely low-k (ELK) dielectric material with a dielectric constant (k) less than about 3.0, or even less than about 2.5. In some embodiments, ELK dielectric materials include carbon-doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂).

In some embodiments, the dielectric materials are deposited using CVD (such as LPCVD, HARP, and FCVD), ALD, spin-on coating, another suitable method, or a combination thereof. A post-curing process (e.g., UV curing) may be performed on the as-deposited ELK dielectric material to form a porous structure.

In some embodiments, the metal lines 120 and the vias 122 are formed using single damascene and/or dual damascene processes. For example, in a dual damascene process, both a trench and a via hole are formed in a dielectric layer, with the via hole underlying and connected to the trench. The conductive material is then deposited to fill the trench and the via hole to form a metal line 120 and a via 122, respectively. In a single damascene process, a via hole is first formed in a dielectric layer, followed by filling the via hole with a conductive material to form a via 122. A trench is first formed in a dielectric layer, followed by filling the trench with a conductive material to form a metal line 120. The deposition process may be CVD, physical vapor deposition (PVD), e-beam evaporation, ALD, electroplating (ECP), electroless deposition (ELD), or a combination thereof.

In some embodiments, the conductive material for the metal lines 120 and the vias 122 may include a diffusion barrier material such as tantalum (Ta), tantalum nitride (TaN), titanium (Ti), titanium nitride (TiN), cobalt tungsten (CoW), another suitable material, or a combination thereof. In some embodiments, the conductive material for the metal lines 120 and the vias 122 may further include a metal bulk material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), another suitable metal material, or a combination thereof over the diffusion barrier material.

A redistribution layer 128 is formed over the interconnect structure 116, as shown in FIG. 1B, in accordance with some embodiments. The redistribution layer 128 includes conductive pads 128A and 128B and a conductive trace 128C connecting between the conductive pads 128A and 128B, as shown in FIG. 1B, in accordance with some embodiments. Although one conductive pad 128A, one conductive pad 128B and one conductive trace 128C are shown in FIG. 1B, there may be more than one conductive pads 128A, more than conductive pads 128B and more than one conductive traces 128C, depending on the design requirements for the resulting device substrate 100.

The conductive pad 128A is located directly on and connected to the topmost via 122A of the thermal conduction structure 124, in accordance with some embodiments. In some embodiments, the conductive pad 128A is a bonding pad, which will be connected to a package substrate in the subsequent packaging process. The thermal conduction structure 124 may provide a vertical thermal conduction path, thereby efficiently dissipating the heat generated from the device layer 104 to the package substrate. The conductive pad 128B is located directly on and connected to the topmost via 122B of the electrical routing structure 126, in accordance with some embodiments.

In some embodiments, the redistribution layer 128 is made of metal material such as copper, aluminum, gold, palladium, cobalt, titanium, nickel, silver, graphene, one or more other suitable metal materials, an alloy thereof, or a combination thereof. The formation of the redistribution layer 128 includes depositing a metal layer on the first passivation layer PAS1 using CVD, PVD, e-beam evaporation, ALD, ECP, ELD, or a combination thereof, and then patterning the metal layer using photolithography and etching processes.

A second passivation layer PAS2 is conformally formed over the redistribution layer 128 and the first passivation layer PAS1, as shown in FIG. 1B, in accordance with some embodiments. In some embodiments, the material and the formation of the second passivation layer PAS2 is the same as or similar to the material and the formation of the first passivation layer PAS1.

The second passivation layer PAS2 is patterned using photolithography and etching processes to form an opening which partially exposes the conductive pad 128A, as shown in FIG. 1B, in accordance with some embodiments. The edge (or sidewalls) of the conductive pad 128A remains covered by the second passivation layer PAS2, in accordance with some embodiments. In addition, the conductive pad 128B remains covered by the second passivation layer PAS2, in accordance with some embodiments.

A polymer layer PI is conformally formed over the second passivation layer PAS2 using a process such as lamination, coating, (e.g., spin-coating), CVD, or the like, as shown in FIG. 1B, in accordance with some embodiments. In some embodiments, the polymer layer PI is made of polymer materials such as epoxy, polyimide, a polybenzoxazole (PBO), or another suitable polymer material.

The polymer layer PI is patterned using photolithography and etching processes to form an opening PIO which corresponds to the opening of the second passivation layer PAS2, as shown in FIG. 1B, in accordance with some embodiments. The opening PIO partially exposes the conductive pad 128A, in accordance with some embodiments. The edge (or sidewalls) of the conductive pad 128A remains covered by the polymer layer PI, in accordance with some embodiments. In addition, the conductive pad 128B remains covered by the polymer layer PI, in accordance with some embodiments.

FIG. 1B-1 is a plan view illustrating the configuration of an opening PIO of a polymer layer PI, a redistribution layer 128, a topmost via 122A of a thermal conduction structure 124, and a topmost via 122B of an electrical routing structure 126 shown in FIG. 1B, in accordance with some embodiments.

The topmost via 122A (in the passivation layer PAS1) of the thermal conduction structure 124 is confined within the area of the opening PIO of the polymer layer PI, as shown in FIG. 1B-1, in accordance with some embodiments. Although not shown, other underlying vias 122A of the thermal conduction structure 124 are also confined within the area of the opening PIO, in accordance with some embodiments.

In some embodiments, the conductive pad 128A has a dimension D1 in a range from about 40 μm to about 70 μm. In some embodiments, the opening PIO has a dimension D2 in a range from about 20 μm to about 50 μm. In some embodiments, the topmost via 122A has a dimension D3 in a range from about 1 μm to about 3 μm. In some embodiments, the dimension of the underlying via 122A is equal to or less than the dimension D3 of the topmost via 122A.

In some embodiments, the ratio (D3/D2) of the dimension D3 of the topmost via 122A to the dimension D2 of the opening PIO is in a range from about 0.02 to about 0.13. If the ratio (D3/D2) is too large, it will negatively affect routing density of the electrical routing structures 126. If the ratio is too small, the thermal conduction structure 124 may not have sufficient thermal conduction efficiency.

The topmost metal line 120A (in the top metal dielectric layer TMD2) of the thermal conduction structure 124 is confined within the area of the opening PIO of the polymer layer PI, in accordance with some embodiments. Although not shown, other underlying metal lines 120A of the thermal conduction structure 124 may be also confined within the area of the opening PIO, in accordance with some embodiments. As a result, all conductive connectors C of the thermal conduction structure 124 are confined within the area of the opening PIO, in accordance with some embodiments.

In some embodiments, the topmost metal line 120A has a length L in the direction parallel to its longitudinal direction and a width W in the direction perpendicular to its longitudinal direction. In some embodiments, the length L and the width W are less than the dimension D2 of the opening PIO. In some embodiments, the dimension (length L or width W) of the underlying metal lines 120A is equal to or less than the dimension (length or width) of the topmost metal line 120B.

The topmost via 122B (in the passivation layer PAS1) of the electrical routing structure 126 is located within the area of the conductive pad 128B, as shown in FIG. 1B-1, in accordance with some embodiments. Although not shown, some of the underlying vias 122B of the electrical routing structure 126 may be located within the area of the conductive pad 128B, and some others may be located outside the area of the conductive pad 128B, which may depend on the design requirements of the integrated circuits, in accordance with some embodiments.

The topmost metal line 120B (in the top metal layer TMD2) of the electrical routing structure 126 overlaps the conductive pad 128B, and may extend beyond the edge (perimeter) of the conductive pad 128B, in accordance with some embodiments. Although not shown, some of the underlying metal lines 120B of the thermal conduction structure 124 may overlap the conductive pad 128B, and some others may not overlap the conductive pad 128B, which may depend on the design requirements of the integrated circuits, in accordance with some embodiments.

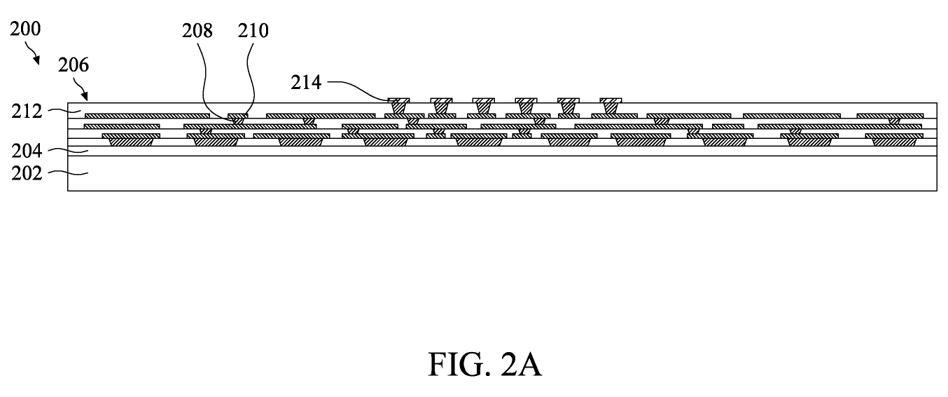

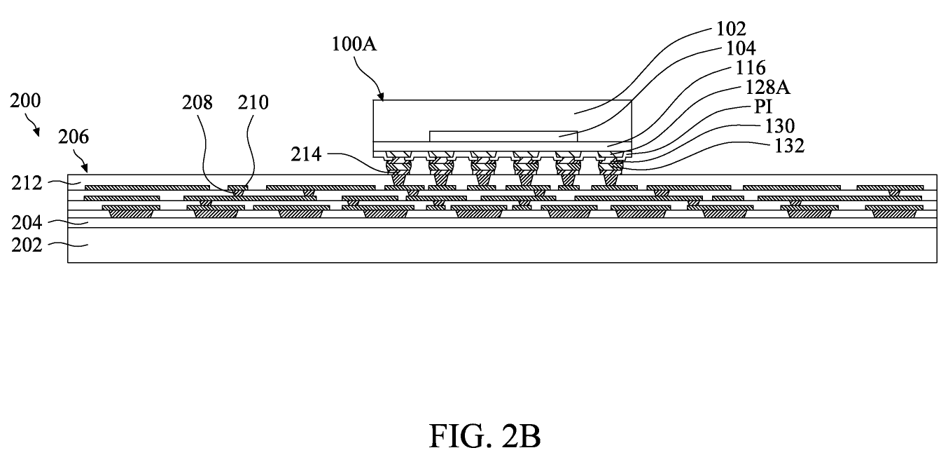

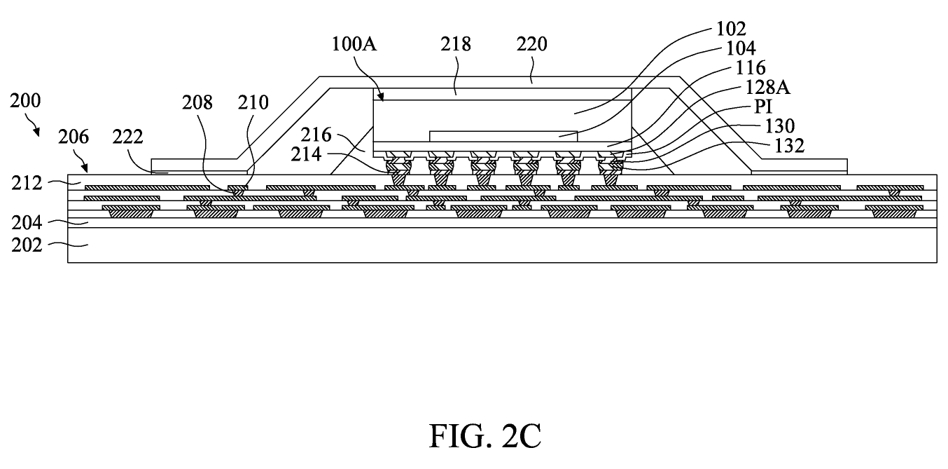

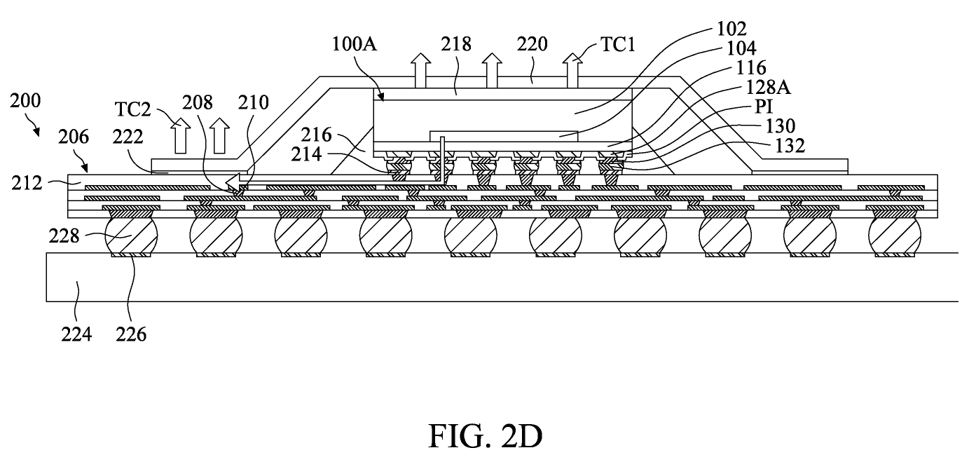

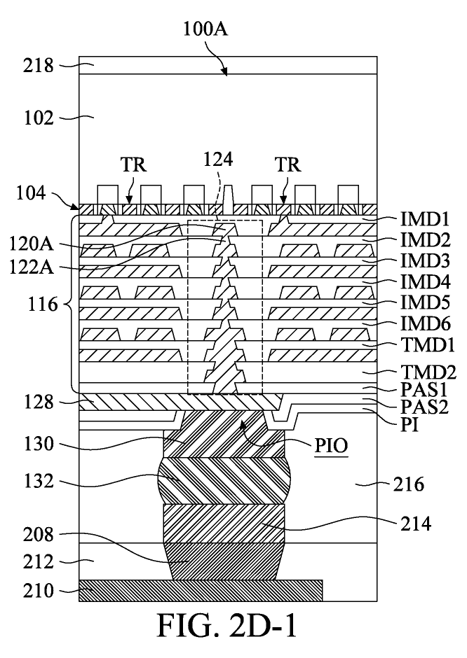

FIG. 1B-2 is a plan view illustrating the configuration of vias 122A of a thermal conduction structure 124 and vias 122B of an electrical routing structure 126 shown in FIG. 1B in different levels, in accordance with some embodiments.

The vias 122A of the thermal conduction structure 124 in different levels overlap with each other, as shown in FIG. 1B-2, in accordance with some embodiments. In some embodiments, the vias 122A in the dielectric layers PAS1, TMD1 and TMD2 are aligned to each other and have the same dimension D3. In some embodiments, the vias 122A in the dielectric layers IMD2, IMD3, IMD4, IMD5 and IMD6 are aligned with each other and have the same dimension D3’ that is less than the dimension D3.

The vias 122A in the dielectric layers IMD2, IMD3, IMD4, IMD5 and IMD6 are confined within the area of the vias 122A in the dielectric layers PAS1, TMD1 and TMD2, in accordance with some embodiments. In some other embodiments, all of the vias 122A may have the same dimension.

Some of the vias 122B (for example, the vias 122B in the dielectric layers IMD4 and IMD5) of the electrical routing structure 126 are located outside the area of the conductive pad 128B, in accordance with some embodiments. As a result, the distance between the vias 122B in neighboring levels is longer than the distance between the vias 122A in neighboring levels, in accordance with some embodiments. Therefore, the thermal conduction structure 124 may provide better thermal conduction efficiency than the electrical routing structure 126.

FIG. 1C illustrates a device substrate 100 after the formation of an under-bump metallurgy structure 130 and a bonding element 132 and a singulation process, in accordance with some embodiments.

An under-bump metallurgy structure (UBM) 130 is formed on the conductive pad 128A and the passivation layer PI to fill the opening PIO, as shown in FIG. 1C, in accordance with some embodiments. In some embodiments, the formation of the under-bump metallurgy structure 130 includes depositing a metal seed layer, forming a patterned mask (not shown) on the metal seed layer, plating a metallic material such as copper into the opening of the patterned mask, removing the patterned mask, and etching the portions of the metal seed layer previously covered by the patterned mask.

In some embodiments, the metal seed layer may include a titanium layer and a copper layer over the titanium layer. The metallic material may be copper, nickel, tantalum, vanadium, chromium, gold, tungsten, an alloy thereof, a multi-layer thereof, or a combination thereof. In some embodiments, the under-bump metallurgy structure 130 is made of non-solder metallic material.

A bonding element 132 is formed on the under-bump metallurgy structure 130, as shown in FIG. 1C, in accordance with some embodiments. In some embodiments, the bump element 132 is a controlled collapse chip connection (C4) bump, a solder joint, a microbump, a solder bump, a solder ball, a ball grid array (BGA) ball, another suitable bonding element, or a combination thereof. In some embodiments, the bonding element 132 is a tin-containing solder bump or solder ball. The tin-containing solder bump or ball may include copper, silver, gold, aluminum, lead, one or more other suitable materials, or a combination thereof. In some embodiments, the bonding element 132 is lead-free.

A singulation (die-saw) process is performed on the device substrate 100 along scribe lines SC to obtain a plurality of semiconductor dies (or chips) 100A which are separate from one another, as shown in FIG. 1C, in accordance with some embodiments. In some embodiments, each of the semiconductor dies 100A includes a semiconductor substrate 102, a device layer 104, an interconnect structure 116 (including the thermal conduction structures 124 and the electrical routing structure 126), a redistribution layer 128, under-bump metallurgy structures 130, and bonding elements 132.

FIG. 1C-1 is a plan view of a semiconductor die 100A shown in FIG. 1C, in accordance with some embodiments of the disclosure. The semiconductor die 100A has a plurality of conductive pads (bonding pads) 128A exposed from the respective opening PIO of the polymer layer PI, as shown in FIG. 1C-1, in accordance with some embodiments.

Each of the conductive pads 128A corresponds to one thermal conduction structure 124 thereunder and one under-bump metallurgy structure 130 thereon, in accordance with some embodiments. In some embodiments, the under-bump metallurgy structures 130 has a dimension D4 that is greater than dimension D1 of the conductive pad 128A. In some embodiments, the dimension D4 is in a range from about 60 μm to about 90 μm.

FIG. 1C-1 only shows one pair of conductive pad 128A and 128B for illustrative purposes. In some embodiments, all of the conductive pads 128B are covered by the polymer layer PI. The signals from the integrated circuits in the device layer 104 may transmit to external devices through the electrical routing structure 126, the redistribution layer 128, the under-bump metallurgy structures 130 and the bonding elements 132, in accordance with some embodiments. Similarly, the power supply from external devices may apply to the integrated circuits in the device layer 104 through the bonding elements 132, the under-bump metallurgy structures 130, the redistribution layer 128, and the electrical routing structure 126.

In accordance with the embodiments of the present disclosure, the semiconductor die 100A includes thermal conduction structures 124, which may provide a thermal conduction path to efficiently dissipate heat from the device layer 104 to the package substrate. Therefore, the thermal conduction structures 124 may help alleviate the heat dissipation issue of the package structure with the semiconductor die 100A. The following describes a method of forming a package structure in which the semiconductor die 100A is packaged.

FIGS. 2A, 2B, 2C and 2D are cross-sectional views illustrating the formation of a package structure at various intermediate stages, in accordance with some embodiments. FIG. 2D-1 is an enlarged view of the package structure of FIG. 2D to illustrate a thermal conduction path through a thermal conduction structure, in accordance with some embodiments.

A package substrate 200 is provided, as shown in FIG. 2A, in accordance with some embodiments. The package substrate 200 includes a carrier substrate 202, an adhesive tape 204 over the carrier substrate 202, and a redistribution structure 206 over the adhesive tape 204, in accordance with some embodiments. In some embodiments, the carrier substrate 202 is a ceramic substrate, a glass substrate, a polymer substrate, a semiconductor substrate, or another suitable substrate.

In some embodiments, the adhesive tape 204 is sensitive to an energy beam irradiation. In some embodiments, the adhesive tape 204 is a release layer that is made of or includes a light-to-heat conversion (LTHC) material. For example, a laser beam may be used to irradiate the adhesive tape 204 in a subsequent process. The irradiation may allow a package structure formed over the adhesive tape 204 to be separated from the carrier substrate 202.

The redistribution structure 206 is configured for routing, which enables the formation of a package structure with fan-out features. In some embodiments, the redistribution structure 206 may be referred to as an interposer substrate. In some embodiments, the redistribution structure 206 includes multiple insulating layers 212 and multiple conductive features 208 and 210 in the insulating layers 212. Although FIG. 2A shows four insulating layers 212, the number of insulating layers is not limited thereto, and the redistribution structure 206 may include more or fewer insulating layers 212.

In some embodiments, the conductive features 208 are vias configured to provide vertical electrical routing. In some embodiments, the conductive features 210 include conductive pads, conductive lines and/or conductive traces configured to provide horizontal electrical routing. In some embodiments, the conductive features 208 land on the conductive pads of the conductive features 210, thereby electrically coupling the conductive features 210 in different insulating layers 212.

In some embodiments, the insulating layers 212 may be made of one or more polymer materials. The polymer materials may include polybenzoxazole (PBO), benzocyclobutene (BCB), polyimide (PI), epoxy-based resin, one or more other suitable polymer materials, or a combination thereof. In some embodiments, the polymer material is photosensitive. In alternative embodiments, the insulating layers 212 are made of one or more dielectric materials such as silicon oxide, silicon nitride and/or silicon oxynitride.

In some embodiments, the conductive features 208 and 210 are made of metallic material such as copper, aluminum, gold, palladium, cobalt, titanium, nickel, silver, graphene, one or more other suitable conductive materials, an alloy thereof, or a combination thereof. In some embodiments, the conductive features 208 and 210 are made of non-solder metallic material. In some embodiments, the conductive features 208 and 210 include multiple sub-layers. For example, each of the conductive features 208 and 210 contains multiple sub-layers including Ti/Cu, Ti/Ni/Cu, Ti/Cu/Ti, Al/Ti/Ni/Ag, other suitable sub-layers, or a combination thereof.

Under-bump metallurgy structures 214 are formed over the upper surface of the redistribution structure 206, as shown in FIG. 2A, in accordance with some embodiments. In some embodiments, each of the under-bump metallurgy structures 214 are formed on and in contact with the respective conductive features 208.

In some embodiments, the under-bump metallurgy structures 214 are used to hold or receive one or more bonding elements such as solder balls. In some embodiments, the formation of the under-bump metallurgy structures 214 includes depositing a metal seed layer, forming a patterned mask (not shown) on the metal seed layer, plating a metallic material such as copper into the opening of the patterned mask, removing the patterned mask, and etching the portions of the metal seed layer previously covered by the patterned mask. In some embodiments, the metal seed layer may include a titanium layer and a copper layer over the titanium layer. The metallic material may be copper, nickel, tantalum, vanadium, chromium, gold, tungsten, an alloy thereof, a multi-layer thereof, or a combination thereof. In some embodiments, the under-bump metallurgy structures 214 are made of non-solder metallic material.

A semiconductor die 100A is disposed over the upper surface of the redistribution structure 206, as shown in FIG. 2B, in accordance with some embodiments. The semiconductor die 100A is bonded to the under-bump metallurgy structures 214 through the bonding elements 132, in accordance with some embodiments. In some embodiments, the semiconductor die 100A is the semiconductor die 100A described above in FIGS. 1C and 1C-1. In some embodiments, the bonding process includes flip-chip bonding, and a thermal reflow operation is carried out.

In some embodiments, the integrated circuits in the device layer 104 of the semiconductor die 100A are electrically coupled to the conductive features 208 and 210 of the redistribution structure 206, in accordance with some embodiments. Although FIG. 2B illustrates that one semiconductor die 100A is on the package substrate 200, the presented disclosure may include more than one semiconductor die on the package substrate 200.

An underfill material 216 is formed over the upper surface of the redistribution structure 206, thereby encapsulating the semiconductor die 100A, as shown in FIG. 2C, in accordance with some embodiments. The underfill material 216 fills the space between the semiconductor die 100A and the package substrate 200 and the space between the bonding elements 132, in accordance with some embodiments.

In some embodiments, the underfill material 216 is an electrically insulated adhesive for protecting the bonding elements 132 and/or securing the semiconductor die 100A. In some embodiments, the underfill material 216 is made of epoxy, resin, epoxy molding compounds, another suitable underfill material, or a combination thereof.

A heat spreader 220 is attached to the backside of the semiconductor die 100A through a thermal interface material (TIM) 218, and attached to the upper surface of the redistribution structure 206 through the film 222, as shown in FIG. 2C, in accordance with some embodiments. In some embodiments, the heat spreader 220 may be made of a conductive material with a relatively high thermal conductivity, e.g., copper, diamond, boron arsenide, silver, silicon, or the like.

In some embodiments, the thermal interface material 218 is configured to ensure good contact between the surfaces of the heat spreader 220 and the substrate 102 of the semiconductor die 100A. The thermal interface material 218 with good thermal conductivity helps to dissipate heat from the semiconductor die 100A to the heat spreader 220. The thermal interface material 218 may include a polymer, resin, or epoxy as a base material, as well as a filler to improve its thermal conductivity. The filler may include a dielectric filler such as alumina, magnesia, aluminum nitride, boron nitride, and diamond powder. In some embodiments, the film 222 may be thermal interface material, or a solder paste.

The carrier substrate 202 is then taken away from the redistribution structure 206 by separating the adhesive tape 204 from the carrier substrate 202 and the redistribution structure 206, as shown in FIG. 2D, in accordance with some embodiments. For example, a release process may be performed by irradiating the structure with an energy beam such as a laser beam, an ultraviolet light, or another suitable energy beam. After the irradiation, the adhesive characteristics of the adhesive tape 204 may be destroyed or reduced.

A package substrate 200 is disposed over and bonded to a wiring substrate 224 through bonding elements 228, as shown in FIG. 2D, in accordance with some embodiments. In some embodiments, the wiring substrate 224 is a printed circuit board (PCB). In alternative embodiments, the wiring substrate 224 is an interposer substrate that may then be bonded to another substrate.

In some embodiments, the wiring substrate 224 is fabricated with a predetermined functional circuit thereon. For example, the functional circuit may include conductive pads, conductive lines, conductive traces, conductive vias and/or active circuitry components such as transistors, diodes, and the like. In some embodiments, the wiring substrate 224 includes conductive pads 226 exposed from and/or protruding from the upper surface of the wiring substrate 224.

In some embodiments, the bonding elements 228 are solder joints, solder balls, ball grid array (BGA) balls, controlled collapse chip connection (C4) bumps, another suitable bonding element, or a combination thereof. In some embodiments, the bonding elements 228 are tin-containing solder balls bumps or solder balls. The tin-containing solder bumps or balls may include copper, silver, gold, aluminum, lead, one or more other suitable materials, or a combination thereof. In some embodiments, the bonding elements 228 are lead-free.

The conductive features 208 of the redistribution structure 206 are bonded to the conductive pads 226 of the wiring substrate 224 through the bonding elements 228, in accordance with some embodiments. In some embodiments, a thermal reflow operation is carried out. As such, the integrated circuits in the device layer 104 of the semiconductor die 100A are electrically coupled to the wiring substrate 224, in accordance with some embodiments.

The package structure may provide two thermal conduction paths TC1 and TC2, as shown in FIG. 2D, in accordance with some embodiments. The first thermal conduction path TC1 may conduct heat from the device heat source to an external heat sink through the thermal interface material 218 and the heat spreader 220, in accordance with some embodiments. Referring to FIGS. 2D and 2D-1, the second thermal conduction path TC2 may conduct heat through the thermal conduction structures 124 in the interconnect structures 116, the conductive pads 128A of the redistribution layer 128, the under-bump metallurgy structures 130, the bonding elements 132, the under-bump metallurgy structures 214, and the conductive features 208 and 210 of the redistribution structure 206, and then through the heat spreader 220. Therefore, the second thermal conduction path TC2 provided by the thermal conduction structures 124 in the semiconductor die 100A may help alleviate the heat dissipation issue of the package structure.

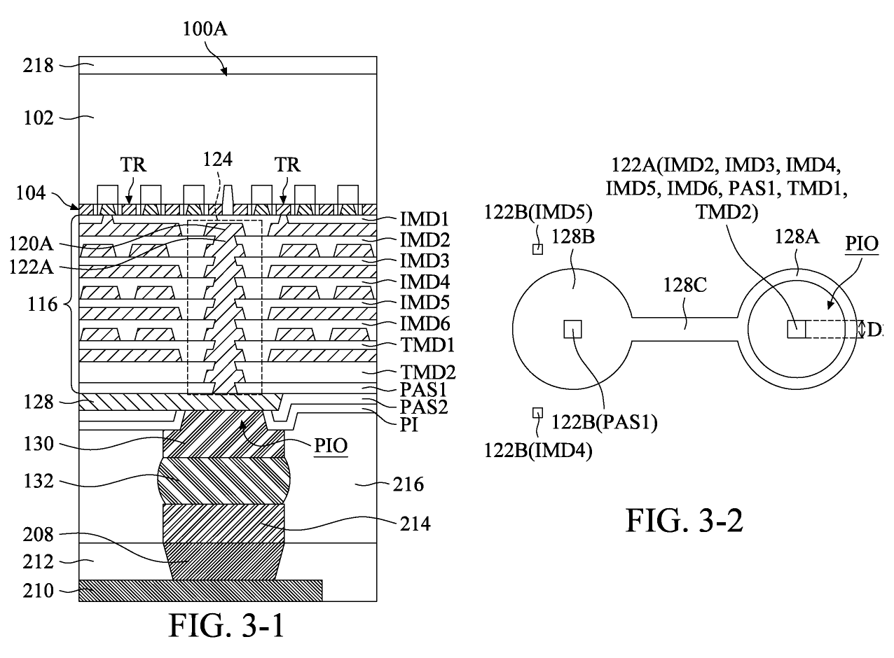

FIG. 3-1 is a modification of FIG. 2D-1, in accordance with some embodiments. FIG. 3-2 is a plan view illustrating the configuration of vias 122A of a thermal conduction structure 124 shown in FIG. 3-1. The thermal conduction structure 124 of FIGS. 3-1 and 3-2 is similar to the thermal conduction structure 124 of FIGS. 1C, 1C-1, 2D and 2D-1, except for the thermal conduction structure 124 of FIGS. 3-1 and 3-2 has the vias 122A of substantially the same size, in accordance with some embodiments.

In some embodiments, the vias 122A of the thermal conduction structure 124 in the dielectric layers IMD2-IMD6, TMD1-TMD2 and PAS1 have substantially the same dimension D3, as shown in FIGS. 3-1 and 3-2. In some embodiments, the sidewalls (edges) of the vias 122A are substantially aligned. In some other embodiments, the vias 122A in different levels may be staggered.

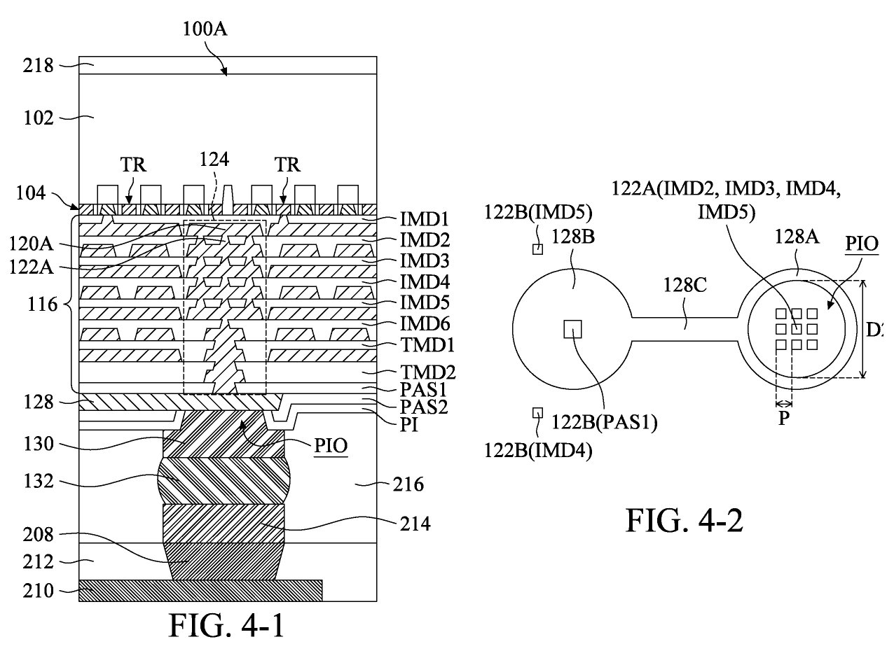

FIG. 4-1 is a modification of FIG. 2D-1, in accordance with some embodiments. FIG. 4-2 is a plan view illustrating the configuration of vias 122A of a thermal conduction structure 124 shown in FIG. 4-1. The thermal conduction structure 124 of FIGS. 4-1 and 4-2 is similar to the thermal conduction structure 124 of FIGS. 1C, 1C-1, 2D and 2D-1, except for the thermal conduction structure 124 of FIGS. 4-1 and 4-2 has multiple vias 122A in a level in the dielectric layers IMD2-IMD6, TMD1-TMD2 and PAS1, in accordance with some embodiments.

In some embodiments, the thermal conduction structure 124 has nine vias 122A in each level in the dielectric layers IMD2-IMD5, as shown in FIGS. 4-1 and 4-2. In some embodiments, the vias 122A in the dielectric layers IMD2-IMD5 are arranged in an array, e.g., a 3X3 array. The vias 122A may be arranged in arrays with other sizes, e.g., a 2×2 array, a 2×3 array, a 3×4 array, a 4×4 array, etc. In some embodiments, the array of vias 122A is confined within the area of the opening PIO.

In some embodiments, the vias 122A in the array have a pitch P that may be less than half of the dimension D2 of the opening PIO. For example, the ratio (P/D2) of the pitch P to the dimension D2 is in a range from about 0.0005 to about 0.2. In some other embodiments, the thermal conduction structure 124 may have multiple vias 122A in one or more levels in the dielectric layers IMD6, TMD1-TMD2 and PAS1.

In accordance with some embodiments, a larger via area can may increase the thermal conductivity of the thermal conduction structure 124, but forming a via hole with a larger size in the lower-level dielectric layer(s) may increase the difficulty of the photolithography process. Therefore, forming multiple vias with smaller sizes may increase thermal conductivity without increasing the difficulty of the photolithography process.

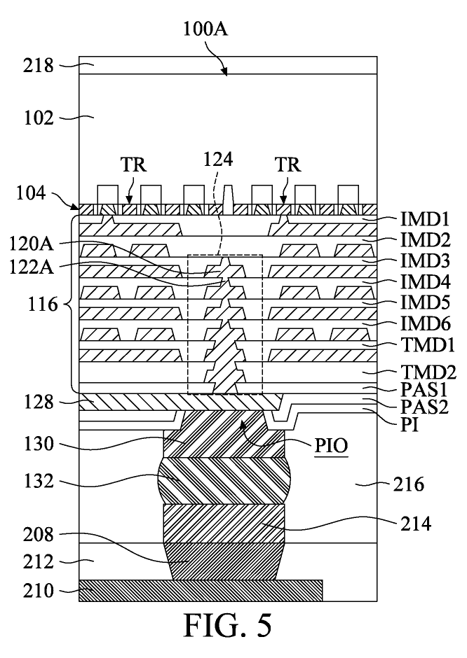

FIG. 5 is a modification of FIG. 2D-1, in accordance with some embodiments. The thermal conduction structure 124 of FIG. 5 is similar to the thermal conduction structure 124 of FIGS. 1C, 1C-1, 2D and 2D-1, except for the thermal conduction structure 124 of FIG. 5 has no conductive connectors in low levels of the dielectric layers, in accordance with some embodiments.

In some embodiments, the bottommost conductive connector of the thermal conduction structure 124 is located in the intermetal dielectric layer IMD3, as shown in FIG. 5, in accordance with some embodiments. The bottommost conductive connector (i.e., the via 122A in the intermetal dielectric layer IMD3) of the thermal conduction structure 124, which is the topmost one in FIG. 5, is separate from the device layer 104 by the intermetal dielectric layers IMD1 and IMD2, in accordance with some embodiments.

Because there may be a higher routing density in low-level dielectric layers (e.g., IMD1 and IMD2), the thermal conduction structure 124 with no conductive connectors in those dielectric layers may improve the routing density and design flexibility of the electrical routing structure 126, in accordance with some embodiments.

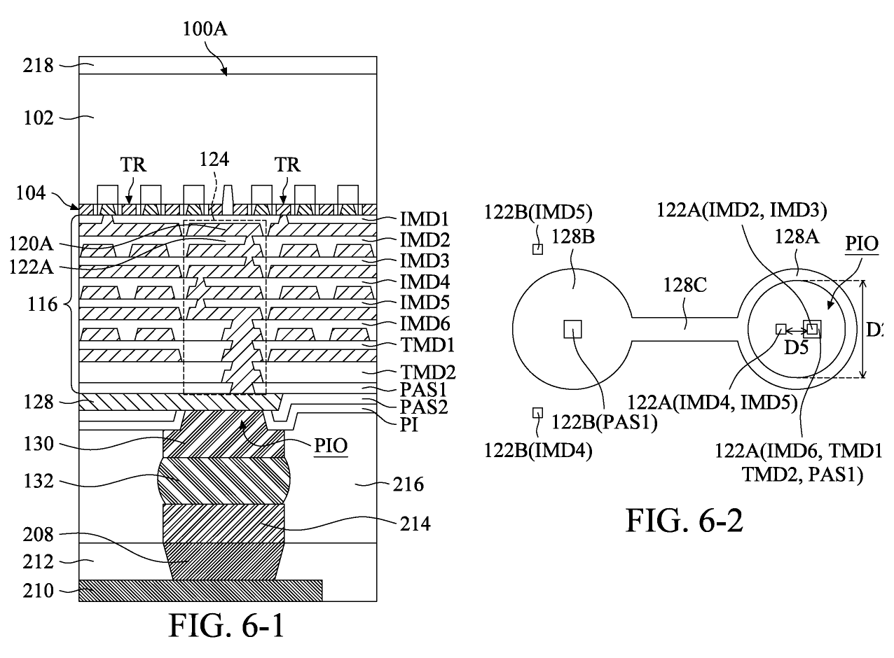

FIG. 6-1 is a modification of FIG. 2D-1, in accordance with some embodiments. FIG. 6-2 is a plan view illustrating the configuration of vias 122A of a thermal conduction structure 124 shown in FIG. 6-1. The thermal conduction structure 124 of FIGS. 6-1 and 6-2 is similar to the thermal conduction structure 124 of FIGS. 1C, 1C-1, 2D and 2D-1, except for the vias 122A of the thermal conduction structure 124 of FIGS. 6-1 and 6-2 in different levels of the dielectric layers IMD2-IMD6, TMD1-TMD2 and PAS1 are not aligned, in accordance with some embodiments.

In some embodiments, the vias 122A in the dielectric layers IMD2, IMD3, IMD6, TMD1-TMD2 and PAS1 are staggered from and do not overlap with the vias 122A in the dielectric layers IMD4 and IMD5, as shown in FIGS. 6-1 and 6-2. In some embodiments, in the plan view, the distance D5 between the vias 122A in the dielectric layers IMD2, IMD3 and IMD6 and the vias 122A in the dielectric layers IMD4 and IMD5 is less than the dimension D2 of the opening PIO, for example, less than half of the dimension D2.

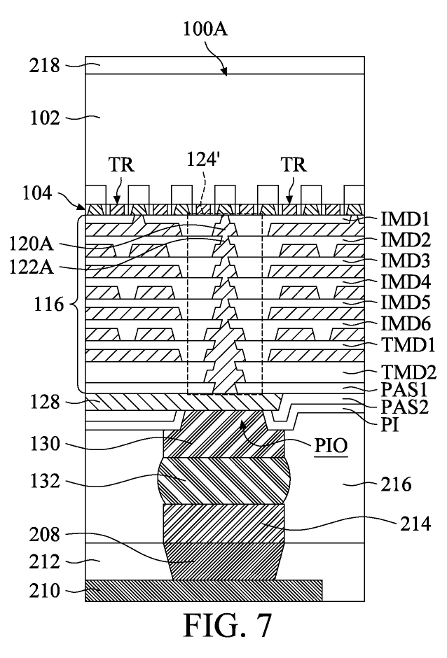

FIG. 7 is a modification of FIG. 2D-1, in accordance with some embodiments. In some embodiments, the semiconductor die 100A may have one or more thermal conduction structures 124’ proximate to the edge of the semiconductor die 100A. The thermal conduction structure 124’ is similar to the thermal conduction structure 124 of FIGS. 1C, 1C-1, 2D and 2D-1, except for the thermal conduction structure 124’ may further provides electrical routing, in accordance with some embodiments.

The bottommost conductive connector (i.e., the metal line 120A and the via 122A in the intermetal dielectric layer IMD1) of the thermal conduction structures 124’ is physically and electrically connected to the transistor TR in the device layer 104, as shown in FIG. 7. In some embodiments, other thermal conduction structures 124 at the center of the semiconductor die 100A remain physically separate from the transistors TR of the device layer 104, as shown in FIG. 2D-1.

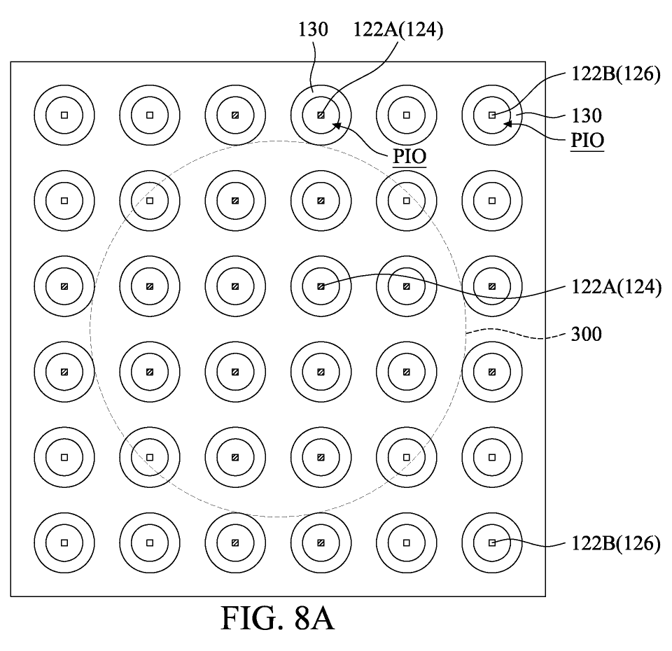

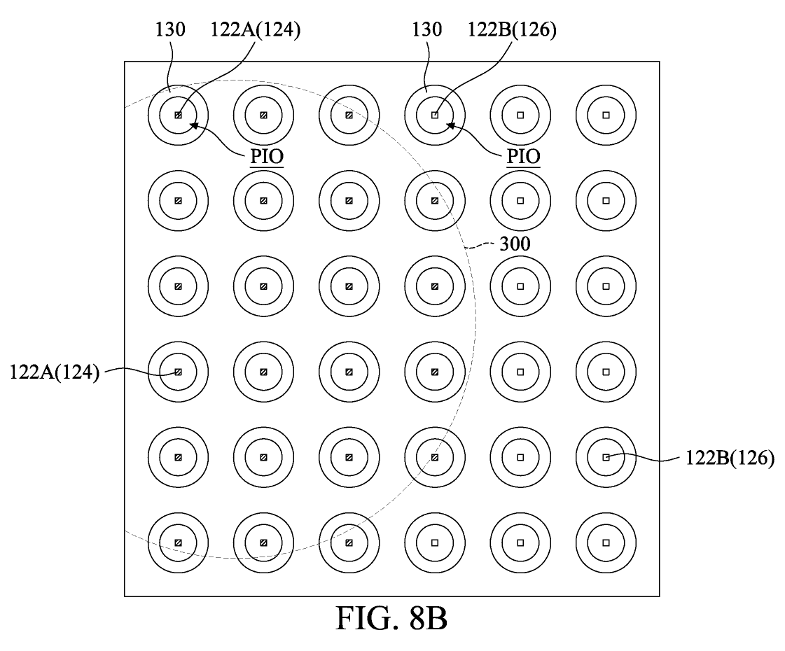

FIG. 8A is a modification of FIG. 1C-1, in accordance with some embodiments of the disclosure. FIG. 8A illustrates a hot zone 300 generated from the device layer 104. In some embodiments, the hot zone 300 may be radiated uniformly from the center point of the semiconductor die 100A. As a result, the configuration of the thermal conduction structures 124 may be adjusted according to the distribution of hot zone 300 so as to improve the routing density while effectively alleviating the heat dissipation issue of the package structure.

The conductive pads 128A are divided into a first group in the center portion of the semiconductor die 100A, and the conductive pads 128A in the first group are connected to the topmost vias 122A of the thermal conduction structures 124, in accordance with some embodiments. The conductive pads 128A are further divided into a second group in the edge portion of the semiconductor die 100A, and the conductive pads 128A in the second group are connected to the topmost vias 122B of the electrical routing structures 126, in accordance with some embodiments. Therefore, the routing density and design flexibility of the electrical routing structure 126 may be improved.

FIG. 8B is a modification of FIG. 1C-1, in accordance with some embodiments of the disclosure. In some embodiments, the hot zone 300 may be non-uniformly radiating, such as being biased to one side (e.g., left side) of semiconductor die 100A. The configuration of the thermal conduction structures 124 may be adjusted according to the distribution of hot zone 300 so as to improve the routing density while effectively alleviating the heat dissipation issue of the package structure.

The conductive pads 128A are divided into a first group in the left portion of the semiconductor die 100A, and the conductive pads 128A in the first group are connected to the topmost vias 122A of the thermal conduction structures 124, in accordance with some embodiments. The conductive pads 128A are further divided into a second group in the right portion of the semiconductor die 100A, and the conductive pads 128A in the second group are connected to the topmost vias 122B of the electrical routing structures 126, in accordance with some embodiments. Therefore, the routing density and design flexibility of the electrical routing structure 126 may be improved.

As described above, the embodiments of the present disclosure provide the device substrate 100 which includes an interconnect structure 116 and a redistribution layer 128 over the interconnect structure 116. Vertically stacked groups of metal lines 120A and vias 122A in the interconnect structure 116 directly under the bonding pads 128A of the redistribution layer 128 serve as thermal conduction structures 124.

In addition, the embodiments of the present disclosure provide the package structure, which includes a redistribution structure 206 and the semiconductor die 100A over the redistribution structure 206. The semiconductor die 100A is singulated from the device substrate 100. Because the semiconductor die 100A includes thermal conduction structures 124, the heat generated from the integrated circuits may efficiently dissipate to the redistribution structure 206. Therefore, the heat dissipation issue of the package structure may be alleviated.

Embodiments of a package structure may be provided. The package structure may include a redistribution structure and a semiconductor die over the redistribution structure. The semiconductor die includes a vertical stacked group of metal lines and vias overlapping with a bonding pad, which may help in dissipating heat generated from the integrated circuits to the redistribution structure. Therefore, the heat dissipation issue of the package structure may be alleviated.

In some embodiments, a package structure is provided. The package structure includes a redistribution structure, a bonding element above the redistribution structure, and a semiconductor die above the bonding element. The semiconductor die includes an interconnect structure. The interconnect structure includes a first group of metal lines electrically connected to the bonding element. The metal lines in the first group vertically overlap with each other. The semiconductor die further includes a first conductive pad between the bonding element and the first group of metal lines. A bottommost one of the metal lines in the first group is a first metal line. In a plan view, a dimension of the first metal line along a first horizontal direction is less than a dimension of the first conductive pad along the first horizontal direction. The package structure includes an underfill material encapsulating the bonding element.

In some embodiments, a package structure is provided. The package structure includes a wiring substrate, a redistribution structure over the wiring substrate, and a semiconductor die over the redistribution structure and electrically connected to the wiring substrate. The semiconductor die includes a device layer including a plurality of transistors, and an interconnect structure under the device layer. The interconnect structure includes stacked levels of dielectric layers and conductive connectors in the respective dielectric layers. The conductive connectors are divided into a plurality of groups. The conductive connectors in a first group are connected to and stacked over one another. A first conductive connector is the conductive connector in the first group that is closest to the device layer. The first conductive connector is isolated from the device layer by a dielectric layer in the dielectric layers.

In some embodiments, a method for forming a package structure is provided. The method includes performing a singulation process to a device substrate to form a semiconductor die. The semiconductor die includes a first metal line, a first via, a second metal line and a second via sequentially stacked, a first conductive pad above the second via, a polymer layer partially covering a top surface of the first conductive pad, and a first under-bump metallurgy structure on the top surface of the first conductive pad. The first under-bump metallurgy structure includes an extending portion surrounded by the polymer layer. In a plan view, the first metal line, the first via, the second metal line and the second via are confined within a perimeter of the extending portion of the first under-bump metallurgy structure. The method further includes bonding the first under-bump metallurgy structure to a first side of a redistribution structure with a plurality of first bonding connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a redistribution structure;
a bonding element above the redistribution structure;
a semiconductor die above the bonding element, wherein the semiconductor die includes an interconnect structure, the interconnect structure includes a first group of metal lines electrically connected to the bonding element, the metal lines in the first group vertically overlap with each other, the semiconductor die further includes a first conductive pad between the bonding element and the first group of metal lines, a bottommost one of the metal lines in the first group is a first metal line, and in a plan view, a dimension of the first metal line along a first horizontal direction is less than a dimension of the first conductive pad along the first horizontal direction; and
an underfill material encapsulating the bonding element.

2. The package structure as claimed in claim 1, wherein in a plan view, a dimension of the first metal line along a second horizontal direction is less than a dimension of the first conductive pad along the second horizontal direction, and the second horizontal direction is perpendicular to the first horizontal direction.

3. The package structure as claimed in claim 1, wherein:
the semiconductor die further includes an under-bump metallurgy structure between the first conductive pad and the bonding element,
the under-bump metallurgy structure includes a lower portion surrounded by the underfill material and an upper portion surrounded by a polymer layer and narrower than the lower portion, and
in the plan view, the dimension of the first metal line along the first horizontal direction is less than a dimension of the upper portion of the under-bump metallurgy structure along the first horizontal direction.

4. The package structure as claimed in claim 3, wherein in the plan view, the dimension of the first metal line along a second horizontal direction is less than a dimension of the upper portion of the under-bump metallurgy structure along the second horizontal direction, and the second horizontal direction is perpendicular to the first horizontal direction.

5. The package structure as claimed in claim 1, further comprising:
a wiring substrate under the redistribution structure and electrically connected to the semiconductor die.

6. The package structure as claimed in claim 1, wherein the first group of metal lines includes a second metal line above the first metal line, and in cross-sectional view, the first metal line is narrower than the second metal line

7. The package structure as claimed in claim 1, wherein the interconnect structure includes a plurality of vias between adjacent two of the metal lines in the first group, and the vias are arranged in a 3X3 array.

8. The package structure as claimed in claim 1, wherein the semiconductor die further includes a plurality of transistors over the interconnect structure, and no conductive feature is sandwiched between a topmost one of the metal lines in the first group and the plurality of transistors.

9. The package structure as claimed in claim 1, wherein:
the semiconductor die further includes a plurality of transistors over the interconnect structure,
the semiconductor die further includes a second conductive pad and a conductive trace between the first conductive pad and the second conductive pad,
the second conductive pad is electrically connected to the plurality of transistors through a second group of metal lines, and
a bottom surface of the second conductive pad is entirely covered by and in direct contact with a dielectric layer.

10. A package structure, comprising:
a wiring substrate;
a redistribution structure over the wiring substrate; and
a semiconductor die over the redistribution structure and electrically connected to the wiring substrate, wherein the semiconductor die includes:
a device layer including a plurality of transistors; and
an interconnect structure under the device layer, wherein the interconnect structure includes stacked levels of dielectric layers and conductive connectors in the respective dielectric layers, the conductive connectors are divided into a plurality of groups, and the conductive connectors in a first group are connected to and stacked over one another, wherein a first conductive connector is the conductive connector in the first group that is closest to the device layer, and the first conductive connector is isolated from the device layer by a dielectric layer in the dielectric layers.

11. The package structure as claimed in claim 10, wherein the conductive connectors in a second group are connected to and stacked over one another, wherein a second conductive connector is the conductive connector in the second group that is closest to the device layer, and the second conductive connector is isolated from the device layer by the dielectric layer.

12. The package structure as claimed in claim 11, further comprising:
a first bump overlying the first group of conductive connectors; and
a second bump overlying the second group of conductive connectors.

13. The package structure as claimed in claim 10, wherein the semiconductor die further includes:
a conductive pad under the first group of conductive connectors, wherein in a plan view, the first group of conductive connectors is entirely confined within the conductive pad; and
a polymer layer partially covering a bottom surface of the conductive pad.

14. The package structure as claimed in claim 13, further comprising:
a first under-bump metallurgy structure under the conductive pad and including an extending portion surrounded by the polymer layer;
a bump under the first under-bump metallurgy structure; and
a second under-bump metallurgy structure under the bump and on a conductive feature of the redistribution structure.

15. The package structure as claimed in claim 14, further comprising:
an underfill material surrounding the first under-bump metallurgy structure, the bump and the second under-bump metallurgy structure.

16. A method for forming a package structure, comprising:
performing a singulation process to a device substrate to form a semiconductor die, wherein the semiconductor die includes:
a first metal line, a first via, a second metal line and a second via sequentially stacked;
a first conductive pad above the second via;
a polymer layer partially covering a top surface of the first conductive pad; and
a first under-bump metallurgy structure on the top surface of the first conductive pad, wherein the first under-bump metallurgy structure includes an extending portion surrounded by the polymer layer, in a plan view, the first metal line, the first via, the second metal line and the second via are confined within a perimeter of the extending portion of the first under-bump metallurgy structure; and
bonding the first under-bump metallurgy structure to a first side of a redistribution structure with a plurality of first bonding connectors.

17. The method for forming the package structure as claimed in claim 16, further comprising:
disposing a thermal interface material over the semiconductor die; and
disposing a heat spreader on the thermal interface material and the first side of the redistribution structure.

18. The method for forming the package structure as claimed in claim 16, wherein the semiconductor die further includes a third metal line, a third via, a fourth metal line and a fourth via sequentially stacked, the fourth via is located under the first metal line, and in the plan view, the third metal line, the third via, the fourth metal line and the fourth via are confined within the perimeter of the extending portion of the first under-bump metallurgy structure.

19. The method for forming the package structure as claimed in claim 16, further comprising:
forming an underfill material to surround a portion of the first under-bump metallurgy structure protruding from the polymer layer and the plurality of first bonding connectors.

20. The method for forming the package structure as claimed in claim 16, further comprising:
bonding a second side of the redistribution structure to a wiring substrate with a plurality of second bonding connectors.
